(19) United States
(12) Patent Application Publication
(10) Pub. No.: US 2015/0200218 A1
(43) Pub. Date: Jul. 16, 2015

(54) IMAGE SENSOR DEVICES AND METHODS FOR FABRICATING THE SAME

(71) Applicant: SILICON OPTRONICS, INC., Hsinchu (TW)

(72) Inventor: Yu-Yuan YAO, Hsinchu (TW)

(73) Assignee: SILICON OPTRONICS, INC., Hsinchu (TW)

(21) Appl. No.: 14/253,287

(22) Filed: Apr. 15, 2014

(30) Foreign Application Priority Data
Jan. 15, 2014 (TW) 103101381

(51) Int. Cl. H01L 27/146

(52) U.S. Cl. CPC H01L 27/14612; H01L 27/14609; H01L 27/14689; H01L 27/14607

(57) ABSTRACT

The present invention provides an image sensor device including a substrate, a channel formed in the substrate, a photoelectric transfer region formed in the substrate adjacent to one side of the channel, a voltage transfer region formed in the substrate adjacent to the other side of the channel, wherein the doping concentration of the channel is decreased from the side adjacent to the photoelectric transfer region to the other side adjacent to the voltage transfer region of the channel, a gate dielectric layer formed on the substrate, and a gate formed on the gate dielectric layer. The present invention also provides a method for fabricating the image sensor device.

### CROSS REFERENCE TO RELATED APPLICATIONS

This Application claims priority of Taiwan Patent Application No. 103101381, filed on Jan. 15, 2014, the entirety of which is incorporated by reference herein.

### TECHNICAL FIELD

The technical field relates to an image sensor device and a method for fabricating the same.

### BACKGROUND

In terms of semiconductor technology, the image sensor device is used to sense the light projecting onto the semiconductor substrate. Common image sensor devices include complementary metal oxide semiconductor (CMOS) image sensor devices and charge coupled device (CCD) sensor devices, widely applied in all respects, for instance, in digital cameras. Those image sensor devices adopt a pixel array to receive light energy in order to transform an image into digital data. The above-mentioned pixel array may include photodiodes (PDs) and transistors. Currently, the structure of CMOS image sensor devices includes 3-T architecture and 4-T architecture. The 3-T architecture may include a reset transistor (RST), source follower (SF) transistor, and row select (RS) transistor etc., while the 4-T architecture may include a transfer transistor (TX), reset transistor (RST), source follower (SF) transistor, and row select (RS) transistor, etc.

The transfer transistor (TX) belonging to the above-mentioned 4-T architecture serves to isolate the photodiode (PD) and the floating diffusion (FD) under an exposure operation or transfer charges from the photodiode (PD) to the floating diffusion (FD) under a readout operation.

Conventionally, the threshold voltage of the transfer transistor can be altered by process adjustment, for example, channel implantation doping, various thicknesses of gate dielectric layer or polysilicon implantation doping, etc. Generally, in the transfer transistor, the threshold voltage along the channel between the photodiode (PD) and the floating diffusion (FD) is uniform. While applying a higher operating voltage than the threshold voltage, the transfer transistor is turned on, and charges are transferred from the photodiode (PD) to the floating diffusion (FD). During this procedure, how to improve charge transfer efficiency is really important. On the other hand, while turning the transfer transistor off, how to prevent charges from leakage from the photodiode (PD) to the channel and to prevent residual charges in the channel from backflow to the photodiode (PD) is then important.

However, based on the conventional structural design of the transfer transistor, the potential energy distribution of the channel cannot be conducive to turn-on and turn-off statuses simultaneously.

### SUMMARY

In an embodiment of the invention, an image sensor device is provided. The image sensor device comprises a substrate; a channel formed in the substrate; a photoelectric transfer region formed in the substrate adjacent to one side of the channel; a voltage transfer region formed in the substrate adjacent to the other side of the channel, wherein the doping concentration of the channel is decreased from the side adjacent to the photoelectric transfer region to the other side adjacent to the voltage transfer region of the channel; a gate dielectric layer formed on the substrate; and a gate formed on the gate dielectric layer.

In another embodiment of the invention, a method for fabricating an image sensor device is provided. The method comprises providing a substrate; forming a channel in the substrate using a gray level mask; forming a gate dielectric layer on the substrate; forming a gate on the gate dielectric layer; forming a photoelectric transfer region in the substrate adjacent to one side of the channel; and forming a voltage transfer region in the substrate adjacent to the other side of the channel, wherein the doping concentration of the channel is decreased from the side adjacent to the photoelectric transfer region to the other side adjacent to the voltage transfer region of the channel.

In the present invention, the potential energy of the channel presents a continuously decreasing status or a stepped decreasing status during the turning on or turning off due to the structural design of the gradient variation of the doping concentration of the channel. When the gate is turned on, the charges are not prone to staying in the channel and are thoroughly transferred to the voltage transfer region due to the lowest potential energy of the channel adjacent to the potential energy of the voltage transfer region, dramatically improving charge transfer efficiency. When the gate is turned off, the charges are not easily leaked from the photoelectric transfer region, for example photodiode (PD), to the channel, and backflow of residual charges in the channel to the photodiode (PD) can be avoided due to the highest potential energy of the channel being significantly higher than the potential energy of the photoelectric transfer region.

A detailed description is given in the following embodiments with reference to the accompanying drawings.

### BRIEF DESCRIPTION OF THE DRAWINGS

The invention can be more fully understood by reading the subsequent detailed descriptions and examples with references made to the accompanying drawings, wherein:

FIG. 1 shows a cross-sectional view of an image sensor device in accordance with an embodiment of the invention;

FIG. 2 shows a cross-sectional view of an image sensor device in accordance with an embodiment of the invention;

FIGS. 3A-3K disclose a method for fabricating an image sensor device in accordance with an embodiment of the invention;

FIGS. 4A-4K disclose a method for fabricating an image sensor device in accordance with an embodiment of the invention;

FIG. 5A shows potential energy statuses of a photoelectric transfer region, a channel and a voltage transfer region when an image sensor device is turned on in accordance with an embodiment of the invention;

FIG. 5B shows potential energy statuses of a photoelectric transfer region, a channel and a voltage transfer region when an image sensor device is turned off in accordance with an embodiment of the invention;

FIG. 6A shows potential energy statuses of a photoelectric transfer region, a channel and a voltage transfer region when an image sensor device is turned on in accordance with an embodiment of the invention; and

FIG. 6B shows potential energy statuses of a photoelectric transfer region, a channel and a voltage transfer region when an image sensor device is turned off in accordance with an embodiment of the invention.

### DETAILED DESCRIPTION

The following description is of the best-contemplated mode of carrying out the invention. This description is made for the purpose of illustrating the general principles of the invention and should not be taken in a limiting sense. The scope of the invention is best determined by reference to the appended claims.

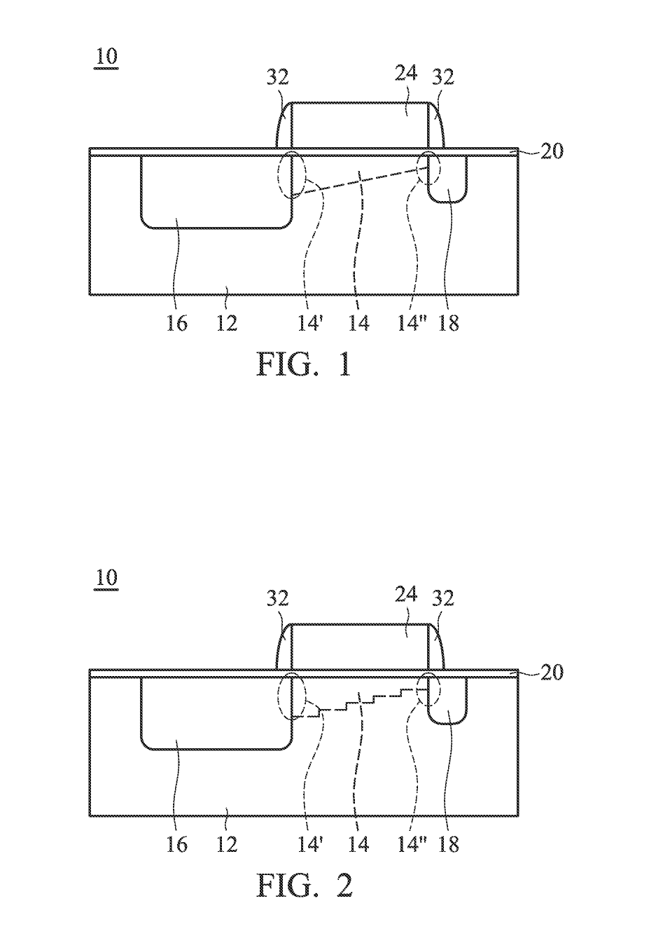

Referring to FIG. 1, according to one embodiment of the invention, an image sensor device is disclosed. The image sensor device 10 comprises a substrate 12, a channel 14 formed in the substrate 12, a photoelectric transfer region 16 formed in the substrate 12 adjacent to one side 14′ of the channel 14, a voltage transfer region 18 formed in the substrate 12 adjacent to the other side 14″ of the channel 14, a gate dielectric layer 20 formed on the substrate 12, and a gate 24 formed on the gate dielectric layer 20. Specifically, the doping concentration of the channel 14 is decreased from the side 14′ adjacent to the photoelectric transfer region 16 to the other side 14″ adjacent to the voltage transfer region 18 of the channel 14. In this embodiment, the doping concentration of the channel 14 is continuously decreased from the side 14′ adjacent to the photoelectric transfer region 16 to the other side 14″ adjacent to the voltage transfer region 18 of the channel 14.

Referring to FIG. 2, according to another embodiment of the invention, an image sensor device is disclosed. The image sensor device 10 comprises a substrate 12, a channel 14 formed in the substrate 12, a photoelectric transfer region 16 formed in the substrate 12 adjacent to one side 14′ of the channel 14, a voltage transfer region 18 formed in the substrate 12 adjacent to the other side 14″ of the channel 14, a gate dielectric layer 20 formed on the substrate 12, and a gate 24 formed on the gate dielectric layer 20. Specifically, the doping concentration of the channel 14 is decreased from the side 14′ adjacent to the photoelectric transfer region 16 to the other side 14″ adjacent to the voltage transfer region 18 of the channel 14. In this embodiment, the doping concentration of the channel 14 is decreased in a stepped manner from the side 14′ adjacent to the photoelectric transfer region 16 to the other side 14″ adjacent to the voltage transfer region 18 of the channel 14.

In one embodiment, the substrate 12 may be a semiconductor substrate such as a silicon substrate doped with p-type dopants. However, the invention is not limited thereto. In other embodiments, the substrate 12 may also comprise other semiconductor materials, for example, elementary semiconductor such as germanium or diamond, etc., or compound semiconductor such as silicon carbide, gallium arsenide, indium arsenide or indium phosphide, etc. In other embodiments, the substrate 12 may also comprise an epitaxial layer on bulk semiconductor, a silicon germanium layer on bulk silicon, a silicon material layer on bulk silicon germanium or silicon-on-insulator (SOI), etc. Additionally, in other embodiments, the substrate 12 may also comprise an epitaxial layer doped with p-type or n-type dopants.

In one embodiment, the photoelectric transfer region 16 may comprise a photoelectric transfer element, for example, a photodiode (PD). In other embodiments, other photoelectric transfer elements may also be applicable.

In one embodiment, the voltage transfer region 18 may be a floating diffusion (FD), which may be regarded as a voltage transfer element, for example, a capacitor structure.

In one embodiment, the gate dielectric layer 20 may comprise silicon oxide, silicon nitride, silicon oxynitride or combinations thereof.

In one embodiment, the gate 24 may comprise polycrystalline silicon or monocrystalline silicon, which may be used as a transfer gate.

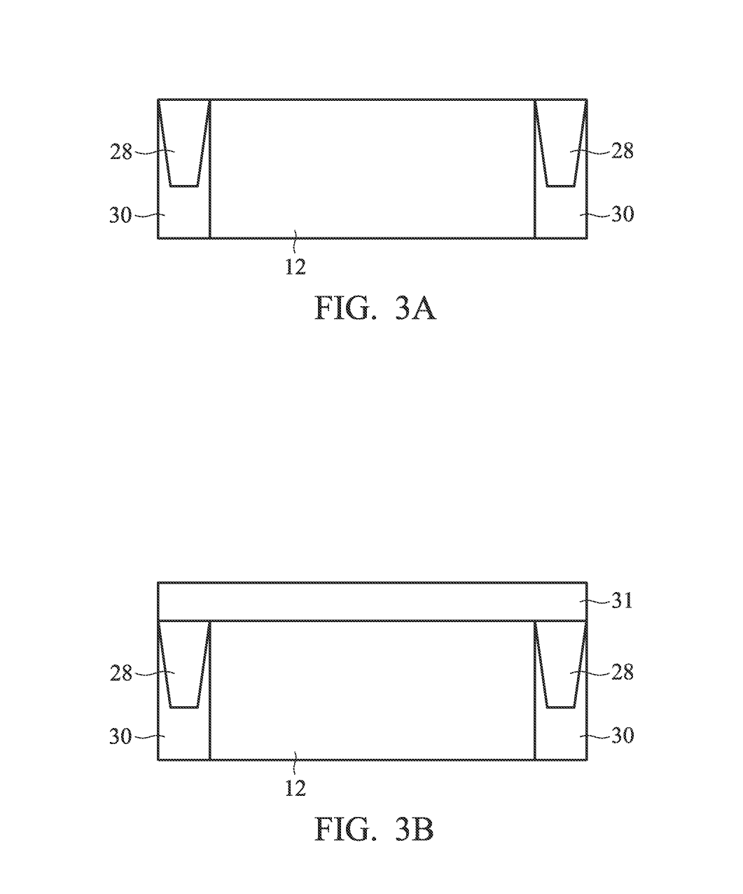

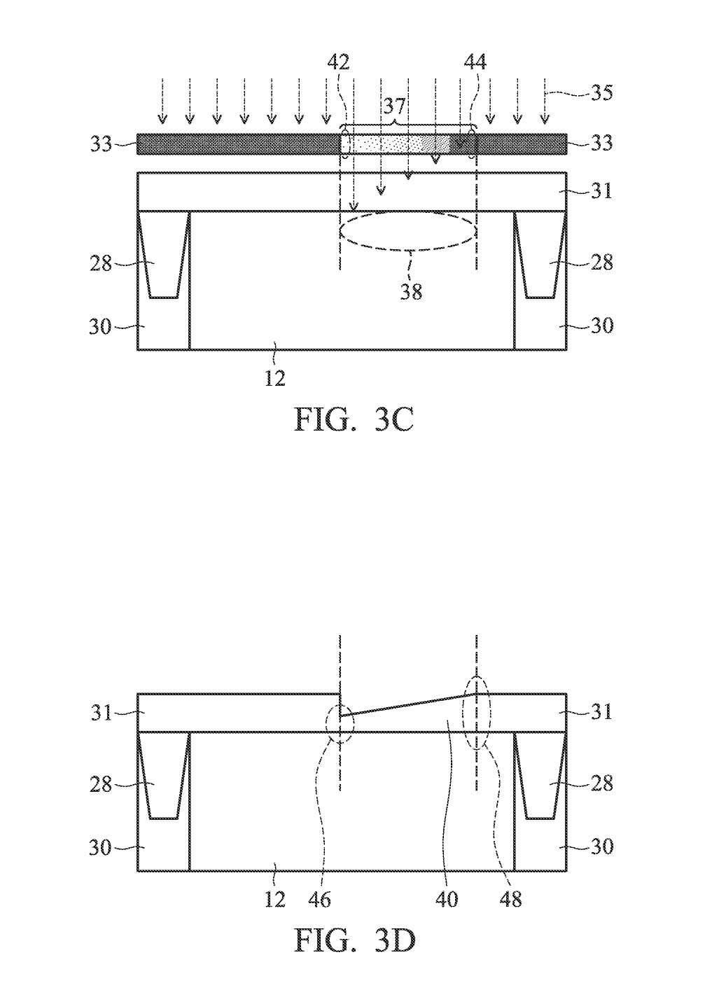

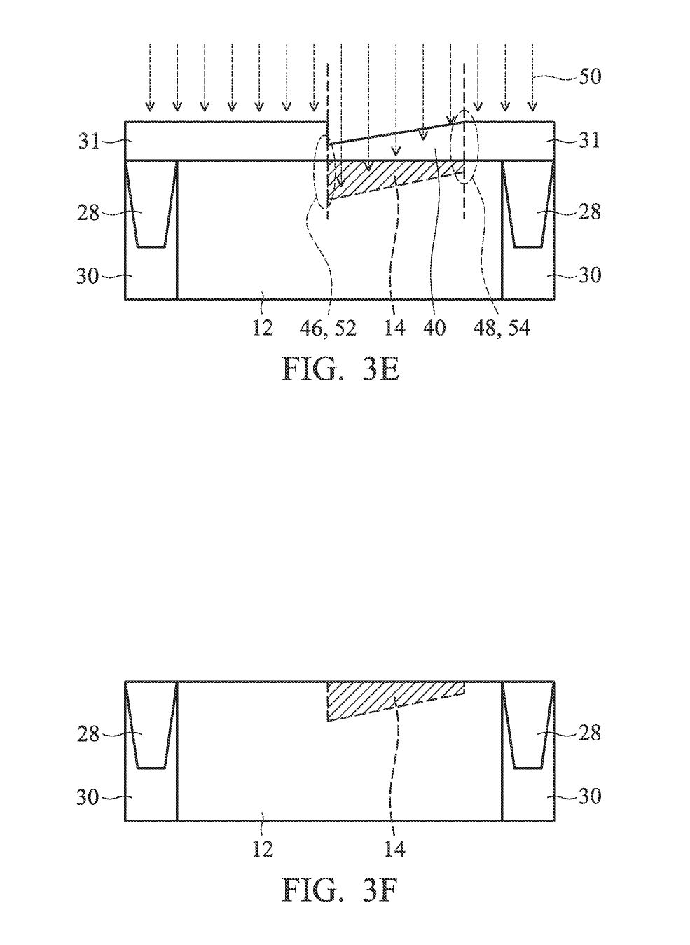

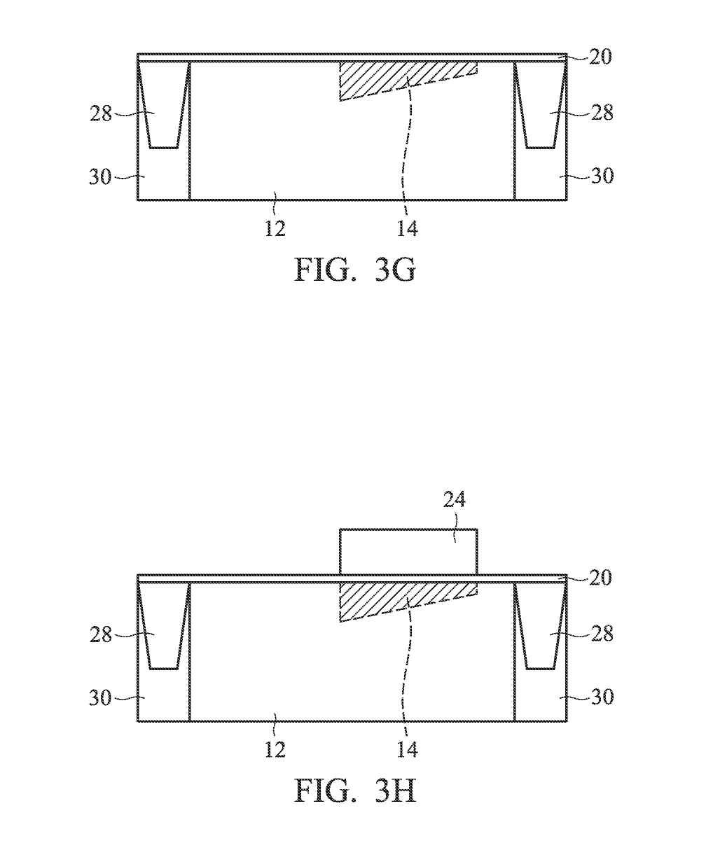

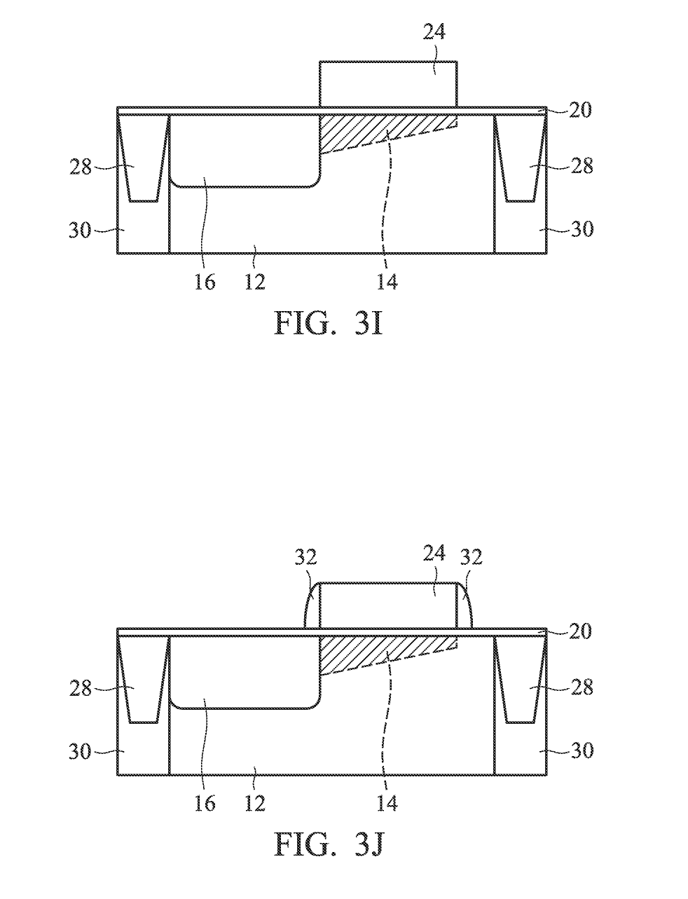

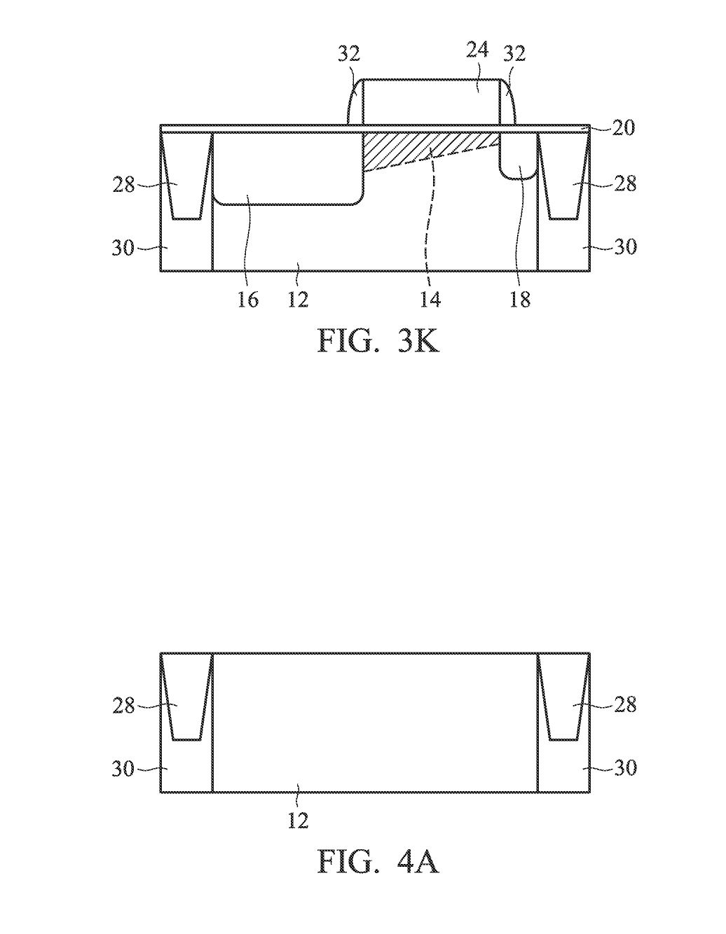

Referring to FIGS. 3A-3K, according to one embodiment of the invention, a method for fabricating an image sensor device is disclosed. First, referring to FIG. 3A, a substrate 12 is provided. In one embodiment, the substrate 12 may be a semiconductor substrate such as a silicon substrate doped with p-type dopants. However, the invention is not limited thereto. In other embodiments, the substrate 12 may also comprise other semiconductor materials, for example, elementary semiconductor such as germanium or diamond, etc., or compound semiconductor such as silicon carbide, gallium arsenide, indium arsenide or indium phosphide, etc. In other embodiments, the substrate 12 may also comprise an epitaxial layer on bulk semiconductor, a silicon germanium layer on bulk silicon, a silicon material layer on bulk silicon germanium or silicon-on-insulator (SOI), etc. Additionally, in other embodiments, the substrate 12 may also comprise an epitaxial layer doped with p-type or n-type dopants.

Next, still referring to FIG. 3A, shallow trench isolations (STIs) 28 and p-type wells (PWs) 30 are fabricated in the substrate 12 by a series of known related processes for fabricating shallow trench isolation (STI) structures and p-type wells (PW).

Next, referring to FIG. 3B, a photoresist layer 31 is covered on the substrate 12.

Next, referring to FIG. 3C, a gray level mask 33 is provided and an exposure process 35 is then performed on the photoresist layer 31 using the gray level mask 33. A region 37 whose transmittance is continuously varied in the gray level mask 33 is aimed at a position 38 for subsequently forming a channel in the substrate 12 and then an exposure process is performed. Specifically, in the region 37 of the gray level mask 33, the transmittance thereof is continuously varied from the left side 42 to the right side 44, for example, continuously decreasing from the left side 42 to the right side 44. That is, the transmittance at the left side 42 is highest, the transmittance at the right side 44 is lowest, and the transmittance between the left side 42 and the right side 44 ranges from the highest transmittance to the lowest transmittance and is continuously decreased toward the right side 44.

Next, referring to FIG. 3D, a patterning process is performed on the photoresist layer 31 to form a photoresist mask 40 served as a mask for subsequent channel implantation. The thickness of the photoresist mask 40 is continuously increased from the left side 46 to the right side 48 after the exposure and patterning processes, as shown in FIG. 3D, due to the continuously decreasing transmittance from the left side 42 to the right side 44 of the region 37 in the gray level mask 33 (as shown in FIG. 3C).

Next, referring to FIG. 3E, a channel implantation 50 is performed on the substrate 12 to define a channel 14 in the substrate 12. The doping concentration of the channel 14 is continuously decreased from the left side 52 to the right side 54 of the channel 14 after the channel implantation due to the continuously increased thickness from the left side 46 to the right side 48 of the photoresist mask 40 which is capable of blocking dopants. After removal of the photoresist layer 31, the channel 14 with a gradient-varied doping concentration is fabricated, as shown in FIG. 3F.

Next, referring to FIG. 3G, a gate dielectric layer 20 is formed on the substrate 12 by related deposition or oxidation processes such as chemical vapor deposition (CVD) or thermal oxidation, etc.

Next, referring to FIG. 3H, a gate 24 is formed on the gate dielectric layer 20 by, for example, low pressure chemical vapor deposition (LPCVD), physical vapor deposition (PVD) with proper silicon source materials or any appropriate related deposition processes. In one embodiment, the gate 24 may comprise polycrystalline silicon or monocrystalline silicon. Specifically, the gate 24 serves as a transfer gate.

Next, referring to FIG. 3I, for example, single or multiple implantation processes are performed on the substrate 12 to form a photoelectric transfer region 16 in the substrate 12 adjacent to one side of the channel 14. In one embodiment, when the substrate 12 is an epitaxial layer doped with p-type dopants, n-type dopants are implanted into the region for subsequently forming the photoelectric transfer region 16 in the substrate 12 to form a PN photoelectric transfer region, for example, forming a photoelectric transfer element of a PN photodiode. In another embodiment, p-type dopants may further be implanted into the surface of the above-mentioned region doped with n-type dopants to form a PNP photoelectric transfer region, for example, forming a photoelectric transfer element of a PNP phototriode.

Next, referring to FIG. 3J, spacers 32 are formed on the sidewalls of the gate 24 by known related processes for fabricating spacers.

Next, referring to FIG. 3K, for example, an implantation process is performed on the substrate 12 to form a voltage transfer region 18 in the substrate 12 adjacent to the other side of the channel 14. In one embodiment, when the substrate 12 is an epitaxial layer doped with p-type dopants, n-type dopants are implanted into the region for subsequently forming the voltage transfer region 18 in the substrate 12 to form a N⁺ voltage transfer region 18. In one embodiment, the voltage transfer region 18 is defined as a floating diffusion (FD), which may be regarded as a voltage transfer element, for example, a capacitor structure. Reiterated here, in the image sensor device of this embodiment, the doping concentration of the channel 14 is continuously decreased from the side adjacent to the photoelectric transfer region 16 to the other side adjacent to the voltage transfer region 18 of the channel 14. The image sensor device of the invention is thereby fabricated.

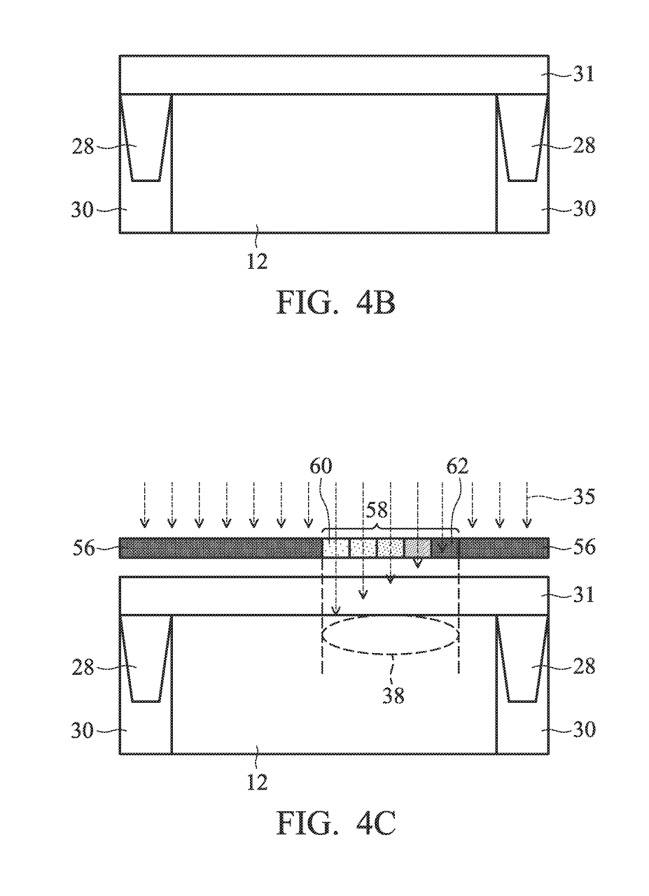

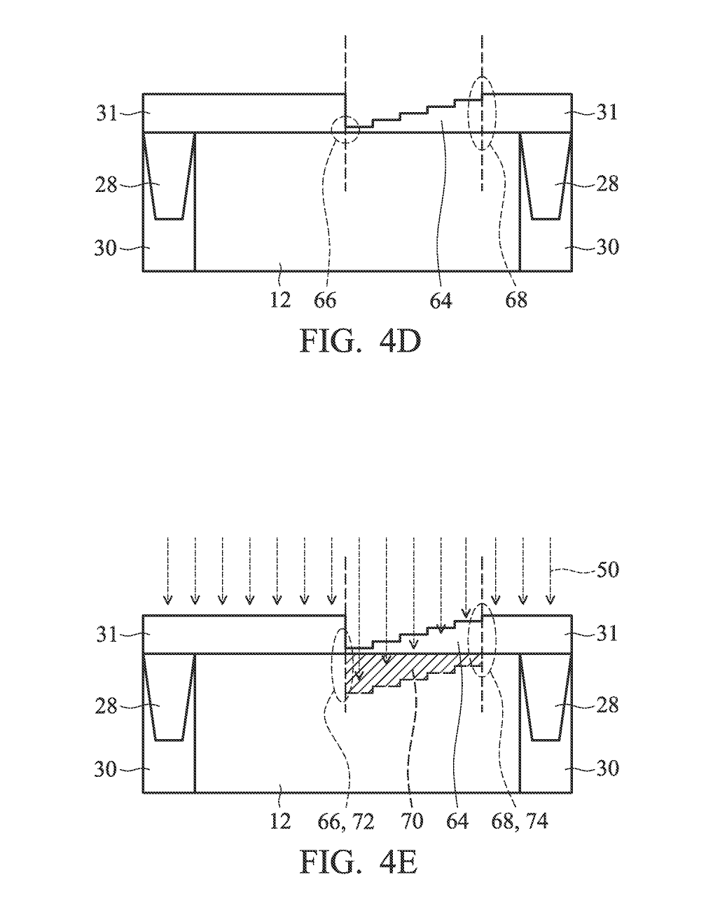

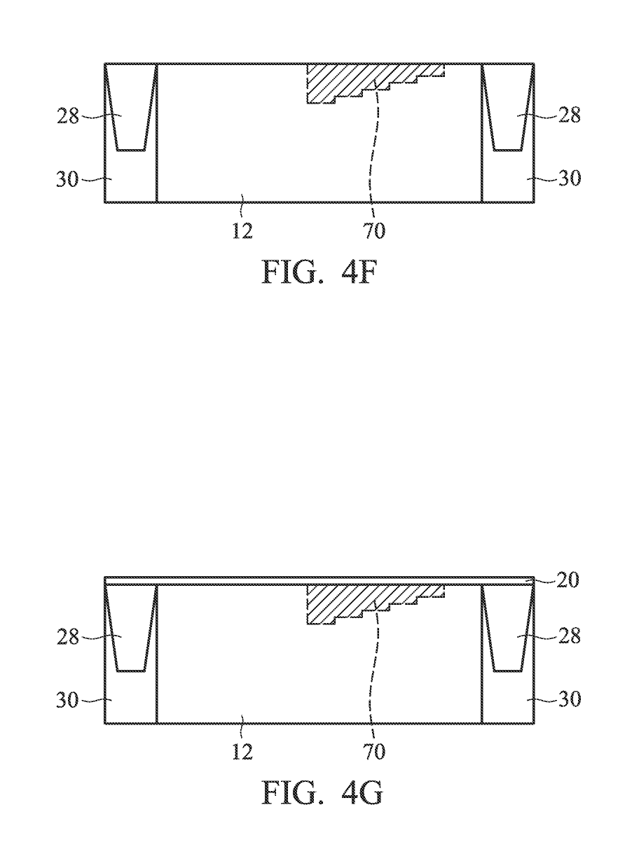

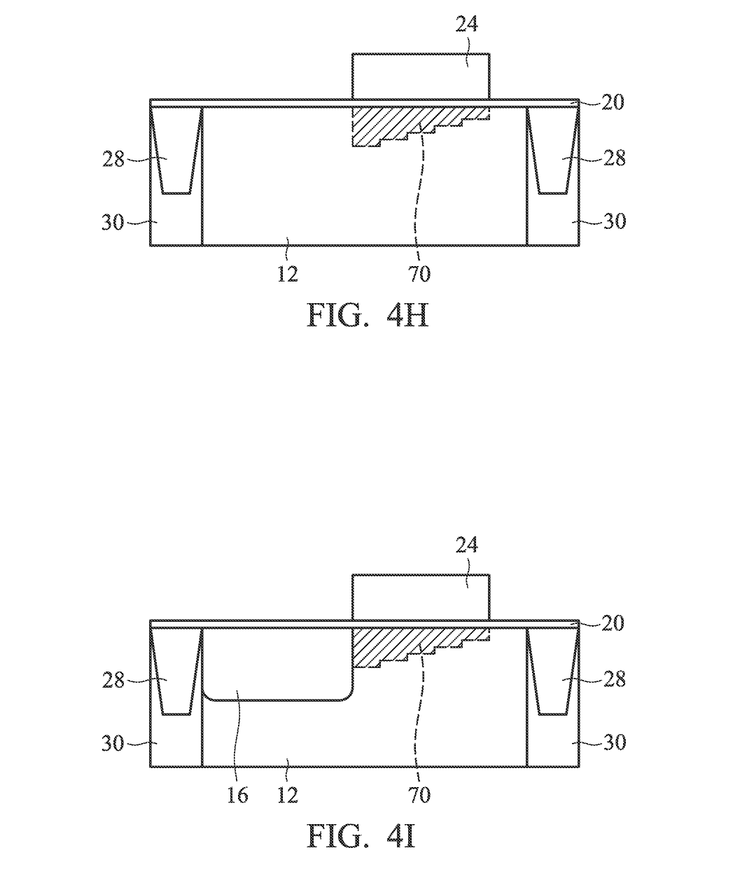

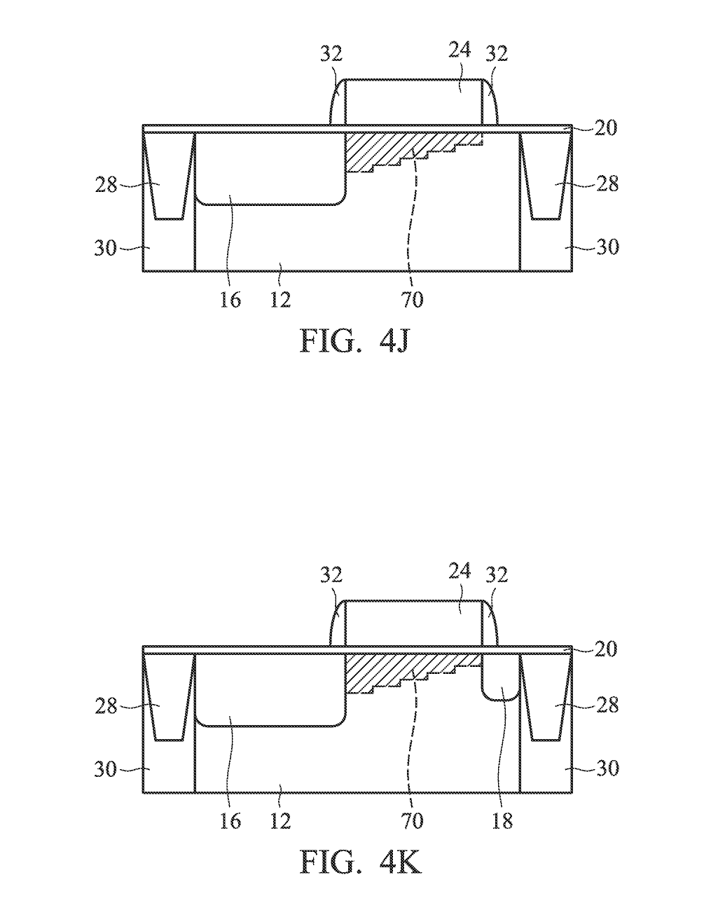

Referring to FIGS. 4A-4K, according to one embodiment of the invention, a method for fabricating an image sensor device is disclosed. First, referring to FIG. 4A, a substrate 12 is provided. In one embodiment, the substrate 12 may be a semiconductor substrate such as a silicon substrate doped with p-type dopants. However, the invention is not limited thereto. In other embodiments, the substrate 12 may also comprise other semiconductor materials, for example, elementary semiconductor such as germanium or diamond, etc., or compound semiconductor such as silicon carbide, gallium arsenide, indium arsenide or indium phosphide, etc. In other embodiments, the substrate 12 may also comprise an epitaxial layer on bulk semiconductor, a silicon germanium layer on bulk silicon, a silicon material layer on bulk silicon germanium or silicon-on-insulator (SOI), etc. Additionally, in other embodiments, the substrate 12 may also comprise an epitaxial layer doped with p-type or n-type dopants.

Next, still referring to FIG. 4A, shallow trench isolations (STIs) 28 and p-type wells (PWs) 30 are fabricated in the substrate 12 by a series of known related processes for fabricating shallow trench isolation (STI) structures and p-type wells (PW).

Next, referring to FIG. 4B, a photoresist layer 31 is covered on the substrate 12.

Next, referring to FIG. 4C, a gray level mask 56 is provided and an exposure process 35 is then performed on the photoresist layer 31 using the gray level mask 56. A region 58 whose transmittance is varied in a stepped manner in the gray level mask 56 is aimed at a position 38 for subsequently forming a channel in the substrate 12 and then an exposure process is performed. Specifically, in the region 58 of the gray level mask 56, the transmittance thereof is varied in a stepped manner from the left side 60 to the right side 62, for example, stepped decreasing from the left side 60 to the right side 62. That is, the transmittance at the left side 60 is highest, the transmittance at the right side 62 is lowest, and the transmittance between the left side 60 and the right side 62 ranges from the highest transmittance to the lowest transmittance and is decreased in a stepped manner toward the right side 62.

Next, referring to FIG. 4D, a patterning process is performed on the photoresist layer 31 to form a photoresist mask 64 that serves as a mask for subsequent channel implantation. The thickness of the photoresist mask 64 is increased in a stepped manner from the left side 66 to the right side 68 after the exposure and patterning processes, as shown in FIG. 4D, due to the stepped decreasing transmittance from the left side 60 to the right side 62 of the region 58 in the gray level mask 56 (as shown in FIG. 4C).

Next, referring to FIG. 4E, a channel implantation 50 is performed on the substrate 12 to define a channel 70 in the substrate 12. The doping concentration of the channel 70 is decreased in a stepped manner from the left side 72 to the right side 74 of the channel 70 after the channel implantation due to the stepped increased thickness from the left side 66 to the right side 68 of the photoresist mask 64 which is capable of blocking dopants. After removal of the photoresist layer 31, the channel 70 with a gradient-varied doping concentration is fabricated, as shown in FIG. 4F.

Next, referring to FIG. 4G, a gate dielectric layer 20 is formed on the substrate 12 by related deposition or oxidation processes such as chemical vapor deposition (CVD) or thermal oxidation, etc.

Next, referring to FIG. 4H, a gate 24 is formed on the gate dielectric layer 20 by, for example, low pressure chemical vapor deposition (LPCVD), physical vapor deposition (PVD) with proper silicon source materials or any appropriate related deposition processes. In one embodiment, the gate 24 may comprise polycrystalline silicon or monocrystalline silicon. Specifically, the gate 24 serves as a transfer gate.

Next, referring to FIG. 4I, for example, single or multiple implantation processes are performed on the substrate 12 to form a photoelectric transfer region 16 in the substrate 12 adjacent to one side of the channel 70. In one embodiment, when the substrate 12 is an epitaxial layer doped with p-type dopants, n-type dopants are implanted into the region for subsequently forming the photoelectric transfer region 16 in the substrate 12 to form a PN photoelectric transfer region, for example, forming a photoelectric transfer element of a PN photodiode. In another embodiment, p-type dopants may further be implanted into the surface of the above-mentioned region doped with n-type dopants to form a PNP photoelectric transfer region, for example, forming a photoelectric transfer element of a PNP phototriode.

Next, referring to FIG. 4J, spacers 32 are formed on the sidewalls of the gate 24 by known related processes for fabricating spacers.

Next, referring to FIG. 4K, for example, an implantation process is performed on the substrate 12 to form a voltage transfer region 18 in the substrate 12 adjacent to the other side of the channel 70. In one embodiment, when the substrate 12 is an epitaxial layer doped with p-type dopants, n-type dopants are implanted into the region for subsequently forming the voltage transfer region 18 in the substrate 12 to form a N⁺ voltage transfer region 18. In one embodiment, the voltage transfer region 18 is defined as a floating diffusion (FD), which may be regarded as a voltage transfer element, for example, a capacitor structure. Reiterated here, in the image sensor device of this embodiment, the doping concentration of the channel 70 is decreased in a stepped manner from the side adjacent to the photoelectric transfer region 16 to the other side adjacent to the voltage transfer region 18 of the channel 70. Therefore, the image sensor device of the invention is fabricated.

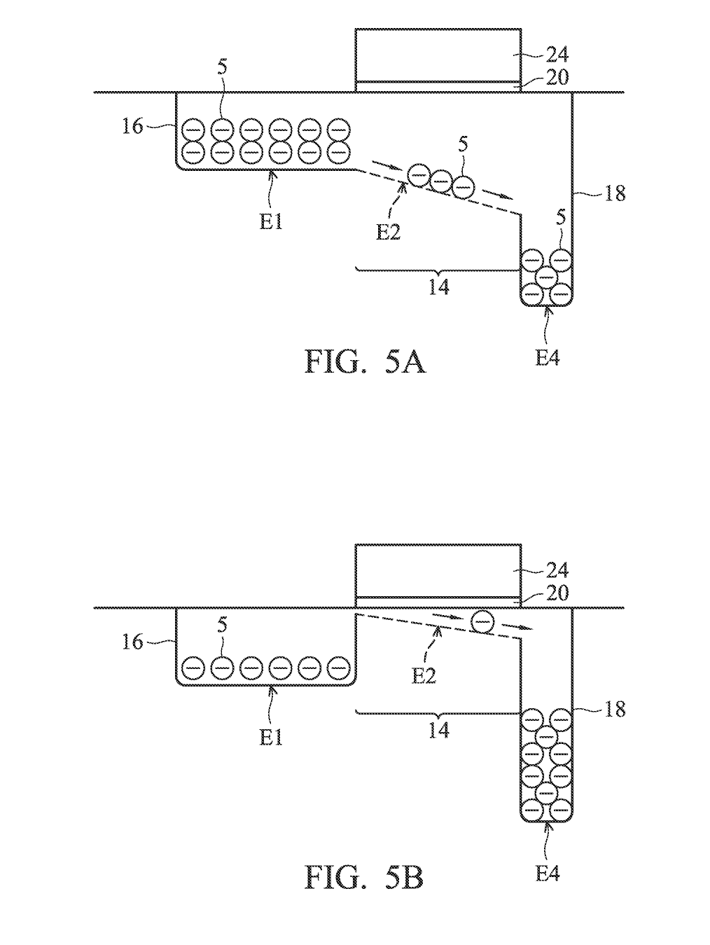

Referring to FIGS. 5A and 5B, the turn-on status and turn-off status of the image sensor device of the invention are described. FIG. 5A shows potential energy statuses of a photoelectric transfer region, a channel and a voltage transfer region when a gate of an image sensor device of the invention is turned on. FIG. 5B shows potential energy statuses of a photoelectric transfer region, a channel and a voltage transfer region when a gate of an image sensor device of the invention is turned off. First, referring to FIG. 5A, when the gate 24 is turned on (applying an operating voltage to the gate 24), the potential energy statuses of the photoelectric transfer region 16, the channel 14 and the voltage transfer region 18 are shown in FIG. 5A, for example, the potential energy E1 of the photoelectric transfer region 16, the potential energy E2 of the channel 14 and the potential energy E4 of the voltage transfer region 18. Specifically, the potential energy E2 of the channel 14 is continuously decreased due to the continuously decreased doping concentration of the channel 14 from the side adjacent to the photoelectric transfer region 16 to the other side adjacent to the voltage transfer region 18 of the channel 14. At this time, the charges 5 accumulated in the photoelectric transfer region 16 by illumination are transferred from the high-potential-energy photoelectric transfer region 16 to the voltage transfer region 18 via the channel 14 to proceed to a read-out process. When turning on, almost all of the charges 5 in the channel 14 are transferred to the voltage transfer region 18 without accumulation in the channel 14 due to the continuously rightward decreased potential energy E2 of the channel 14 toward and adjacent to the potential energy E4 of the voltage transfer region 18, dramatically improving charge transfer efficiency.

Next, referring to FIG. 5B, when the gate 24 is turned off, the potential energy statuses of the photoelectric transfer region 16, the channel 14 and the voltage transfer region 18 are shown in FIG. 5B, including the potential energy E1 of the photoelectric transfer region 16, the potential energy E2 of the channel 14 and the potential energy E4 of the voltage transfer region 18. Specifically, the potential energy E2 of the channel 14 is continuously decreased due to the continuously decreased doping concentration of the channel 14 from the side adjacent to the photoelectric transfer region 16 to the other side adjacent to the voltage transfer region 18 of the channel 14. At this time, the charges 5 are not easily leaked from the photoelectric transfer region 16 to the channel 14 and backflow of residual charges in the channel 14 to the photoelectric transfer region 16 is not prone to occur due to the potential energy E2 of the channel 14 being significantly higher than the potential energy E1 of the photoelectric transfer region 16, achieving excellent turn-off results.

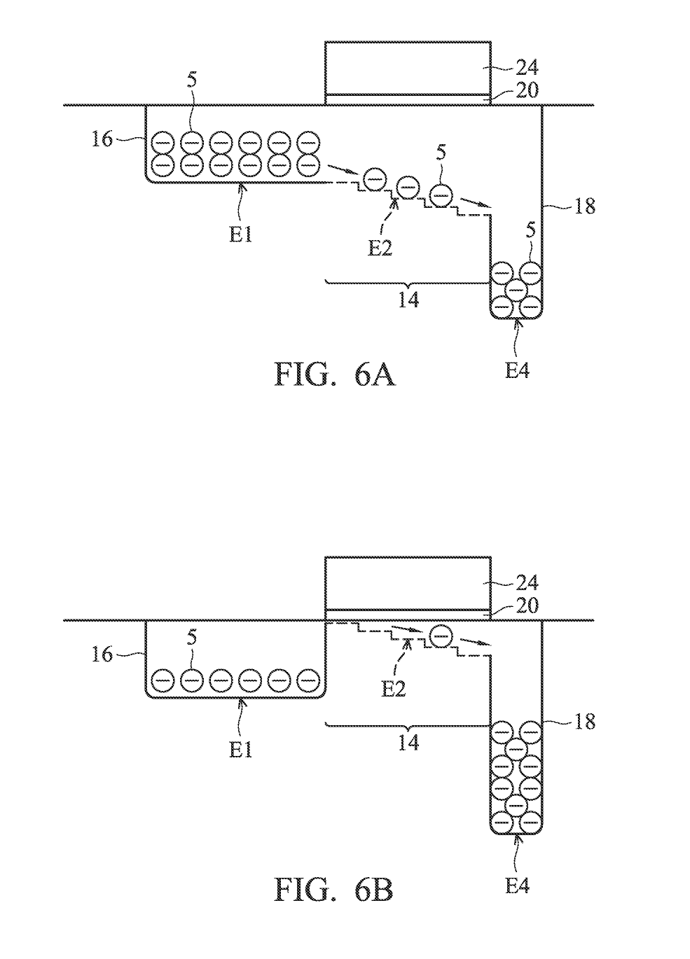

Referring to FIGS. 6A and 6B, according to another embodiment of the invention, the turn-on status and turn-off status of the image sensor device of the invention are described. FIG. 6A shows potential energy statuses of a photoelectric transfer region, a channel and a voltage transfer region when a gate of an image sensor device of the invention is turned on. FIG. 6B shows potential energy statuses of a photoelectric transfer region, a channel and a voltage transfer region when a gate of an image sensor device of the invention is turned off. First, referring to FIG. 6A, when the gate 24 is turned on (applying an operating voltage to the gate 24), the potential energy statuses of the photoelectric transfer region 16, the channel 14 and the voltage transfer region 18 are shown in FIG. 6A, for example, the potential energy E1 of the photoelectric transfer region 16, the potential energy E2 of the channel 14 and the potential energy E4 of the voltage transfer region 18. Specifically, the potential energy E2 of the channel 14 is decreased in a stepped manner due to the stepped decreased doping concentration of the channel 14 from the side adjacent to the photoelectric transfer region 16 to the other side adjacent to the voltage transfer region 18 of the channel 14. At this time, the charges 5 accumulated in the photoelectric transfer region 16 by illumination are transferred from the high-potential-energy photoelectric transfer region 16 to the voltage transfer region 18 via the channel 14 to proceed to a read-out process. When turning on, almost all of the charges 5 in the channel 14 are transferred to the voltage transfer region 18 without accumulation in the channel 14 due to the stepped rightward decreased potential energy E2 of the channel 14 toward and adjacent to the potential energy E4 of the voltage transfer region 18, dramatically improving charge transfer efficiency.

Next, referring to FIG. 6B, when the gate 24 is turned off, the potential energy statuses of the photoelectric transfer region 16, the channel 14 and the voltage transfer region 18 are shown in FIG. 6B, including the potential energy E1 of the photoelectric transfer region 16, the potential energy E2 of the channel 14 and the potential energy E4 of the voltage transfer region 18. Specifically, the potential energy E2 of the channel 14 is decreased in a stepped manner due to the stepped decreased doping concentration of the channel 14 from the side adjacent to the photoelectric transfer region 16 to the other side adjacent to the voltage transfer region 18 of the channel 14. At this time, the charges 5 are not easily leaked from the photoelectric transfer region 16 to the channel 14 and backflow of residual charges in the channel 14 to the photoelectric transfer region 16 is not prone to occur due to the potential energy E2 of the channel 14 being significantly higher than the potential energy E1 of the photoelectric transfer region 16, achieving excellent turn-off results.

In the present invention, the potential energy of the channel presents a continuously decreasing status or a stepped decreasing status during the turning on or turning off due to the structural design of the gradient variation of the doping concentration of the channel. When the gate is turned on, the charges are not prone to staying in the channel and are thoroughly transferred to the voltage transfer region due to the lowest potential energy of the channel adjacent to the potential energy of the voltage transfer region, dramatically improving charge transfer efficiency. When the gate is turned off, the charges are not easily leaked from the photoelectric transfer region, for example photodiode (PD), to the channel, and backflow of residual charges in the channel to the photodiode (PD) can be avoided due to the highest potential energy of the channel being significantly higher than the potential energy of the photoelectric transfer region.

It will be apparent to those skilled in the art that various modifications and variations can be made to the disclosed embodiments. It is intended that the specification and examples be considered as exemplary only, with the true scope of the invention being indicated by the following claims and their equivalents.

What is claimed is:

1. An image sensor device, comprising:
a substrate;
a channel formed in the substrate;
a photoelectric transfer region formed in the substrate adjacent to one side of the channel;
a voltage transfer region formed in the substrate adjacent to the other side of the channel, wherein the doping concentration of the channel is decreased from the side adjacent to the photoelectric transfer region to the other side adjacent to the voltage transfer region of the channel;
a gate dielectric layer formed on the substrate; and
a gate formed on the gate dielectric layer.

2. The image sensor device as claimed in claim 1, wherein the photoelectric transfer region comprises a photodiode (PD).

3. The image sensor device as claimed in claim 1, wherein the voltage transfer region is a floating diffusion (FD).

4. The image sensor device as claimed in claim 1, wherein the voltage transfer region comprises a capacitor.

5. The image sensor device as claimed in claim 1, wherein the doping concentration of the channel is continuously decreased from the side adjacent to the photoelectric transfer region to the other side adjacent to the voltage transfer region of the channel.

6. The image sensor device as claimed in claim 1, wherein the doping concentration of the channel is decreased in a stepped manner from the side adjacent to the photoelectric transfer region to the other side adjacent to the voltage transfer region of the channel.

7. The image sensor device as claimed in claim 1, wherein the gate is a transfer gate.

8. A method for fabricating an image sensor device, comprising:
providing a substrate;
forming a channel in the substrate using a gray level mask;
forming a gate dielectric layer on the substrate;
forming a gate on the gate dielectric layer;
forming a photoelectric transfer region in the substrate adjacent to one side of the channel; and
forming a voltage transfer region in the substrate adjacent to the other side of the channel, wherein the doping concentration of the channel is decreased from the side adjacent to the photoelectric transfer region to the other side adjacent to the voltage transfer region of the channel.

9. The method for fabricating an image sensor device as claimed in claim 8, wherein the transmittance of the gray level mask is continuously varied.

10. The method for fabricating an image sensor device as claimed in claim 9, wherein the doping concentration of the channel is continuously decreased from the side adjacent to the photoelectric transfer region to the other side adjacent to the voltage transfer region of the channel.

11. The method for fabricating an image sensor device as claimed in claim 8, wherein the transmittance of the gray level mask is varied in a stepped manner.

12. The method for fabricating an image sensor device as claimed in claim 11, wherein the doping concentration of the channel is decreased in a stepped manner from the side adjacent to the photoelectric transfer region to the other side adjacent to the voltage transfer region of the channel.
